(19) United States
(12) Patent Application Publication
(10) Pub. No.: US 2010/0054042 A1
(43) Pub. Date: Mar. 4, 2010

(54) SEMICONDUCTOR MEMORY DEVICE AND METHOD OF INSPECTING THE SAME

(75) Inventor: Kazuhiko Miki, Yokoham-shi (JP)

Correspondence Address: TUROCY & WATSON, LLP, 127 Public Square, 57th Floor, Key Tower, CLEVELAND, OH, 44114, US

(73) Assignee: Kabushiki Kaisha Toshiba, Tokyo (JP)

(21) Appl. No.: 12/542,105

(22) Filed: Aug. 17, 2009

(30) Foreign Application Priority Data
Aug. 27, 2008 (JP) 2008-218507

(51) Int. Cl. G11C 7/02; G11C 16/06; G11C 5/14

(52) U.S. Cl. 365/185.21; 365/208; 365/189.09

(57) ABSTRACT

A semiconductor memory device comprises a sense amplifier circuit having a first and a second input terminal, the sense amplifier configured to compare current flowing in the first input terminal with current flowing in the second input terminal, and the sense amplifier configured to provide the result to external; a first gate circuit connected to the first input terminal, the first gate circuit configured to pass a cell current flowing in a memory cell to the first input terminal; a reference current source, the reference current source configured to feed a reference current to the second input terminal, the reference current serving as the reference for level sensing the cell current; a second gate circuit connected to the second input terminal, the second gate circuit including a replica circuit of the first gate circuit; a first current source configured to feed a first current to the first input terminal, the first current corresponding to the offset at the time of read from a first-state cell; and a second current source configured to feed a second current to the second input terminal, the second current corresponding to the offset at the time of read from a second-state cell.

### CROSS-REFERENCE TO RELATED APPLICATION

This application is based upon and claims the benefit of priority from the prior Japanese Patent Application No. 2008-218507, filed on Aug. 27, 2008, the entire contents of which are incorporated herein by reference.

### BACKGROUND OF THE INVENTION

1. Field of the Invention

The present invention relates to a semiconductor memory device, and more particularly to a read circuit in a semiconductor memory device.

2. Description of the Related Art

In reading data out of a memory cell of which current is small, such as a flash memory, an offset current in a sense amplifier circuit contained in a read circuit and a leakage current through a non-selected column may cause failed read. Particularly, in environments that require high-temperature operation, the leakage current increases and the influence therefrom becomes not negligible. Therefore, there have been proposed several semiconductor memory devices capable of preventing failed read caused by the leakage current and methods of controlling the same (see Patent Document 1: JP 6-251593A and so forth).

On the other hand, as for products with disturbance currents such as the offset current and the leakage current exceeding a certain tolerable value, it is also required to consider screening in an inspection stage.

A conventional screening method with a measurement of the disturbance current or the cell current, however, takes time for the measurement and results in an increase in production cost. A test method using a replicated read circuit requires consideration of a correlation with a read circuit actually used in operation and thus lacks in reliability of the inspection result as a problem.

### SUMMARY OF THE INVENTION

In an aspect the present invention provides a semiconductor memory device, comprising: a sense amplifier circuit having a first and a second input terminal, the sense amplifier configured to compare current flowing in the first input terminal with current flowing in second input terminal, and the sense amplifier configured to provide the result to external; a first gate circuit connected to the first input terminal, the first gate circuit configured to pass a cell current flowing in a memory cell to the first input terminal; a reference current source, the reference current source configured to feed a reference current to the second input terminal, the reference current serving as the reference for level sensing the cell current; a second gate circuit connected to the second input terminal, the second gate circuit including a replica circuit of the first gate circuit; a first current source configured to feed a first current to the first input terminal, the first current corresponding to the offset at the time of read from a first-state cell; and a second current source configured to feed a second current to the second input terminal, the second current corresponding to the offset at the time of read from a second-state cell.

In another aspect the present invention provides a semiconductor memory device, comprising: a sense amplifier circuit having a first and a second input terminal, the sense amplifier configured to compare currents flowing in the first input terminal with current flowing in the second input terminal, and the sense amplifier configured to provide the result to external; a first gate circuit connected to the first input terminal, the first gate circuit configured to pass a cell current flowing in a memory cell to the first input terminal; a reference current source, the reference current source configured to feed a reference current to the second input terminal, the reference current serving as the reference for level sensing the cell current; a second gate circuit connected to the second input terminal, the second gate circuit including a replica circuit of the first gate circuit; a first current source configured to feed a first current to the first input terminal, the first current being equal to or smaller than the maximum tolerable value, at which the sense amplifier circuit is normally operable, of a sum current of a difference obtained by subtracting a first bias current flowing in the first input terminal from a second bias current flowing in the second input terminal and a difference obtained by subtracting an off-leakage current through the first gate circuit from an off-leakage current through the second gate circuit; and a second current source configured to feed a second current to the second input terminal, the second current being equal to or smaller than the maximum tolerable value, at which the sense amplifier circuit is normally operable, of a sum current of a difference obtained by subtracting the second bias current from the first bias current and a difference obtained by subtracting the off-leakage current through the second gate circuit from the off-leakage current through the first gate circuit.

In an aspect the present invention provides a method of inspecting semiconductor memory devices, comprising: feeding a previously set current from the first current source to the semiconductor memory device as recited above while keeping the first and second gate circuits turned off to confirm that a first expected value is provided from the sense amplifier circuit; and feeding a previously set current from the second current source to the semiconductor memory device while keeping the first and second gate circuits turned off to confirm that a second expected value is provided from the sense amplifier circuit.

### BRIEF DESCRIPTION OF THE DRAWINGS

FIG. 1 is a circuit diagram showing a read circuit part in a semiconductor memory device according to a first embodiment of the present invention.

FIG. 2 is a block diagram of a system including the same semiconductor memory device.

FIG. 3 is a block diagram of another system including the same semiconductor memory device.

FIG. 4 is a circuit diagram showing a read circuit part in a semiconductor memory device according to a second embodiment of the present invention.

FIG. 5 is a circuit diagram showing a read circuit part in a semiconductor memory device according to a third embodiment of the present invention.

FIG. 6 is a block diagram of a semiconductor memory device according to a fourth embodiment of the present invention.

### DETAILED DESCRIPTION OF THE EMBODIMENTS

The embodiments associated with the semiconductor memory device according to the present invention will now be described in detail with reference to the drawings.

### First Embodiment

### [Configuration of Semiconductor Memory Device]

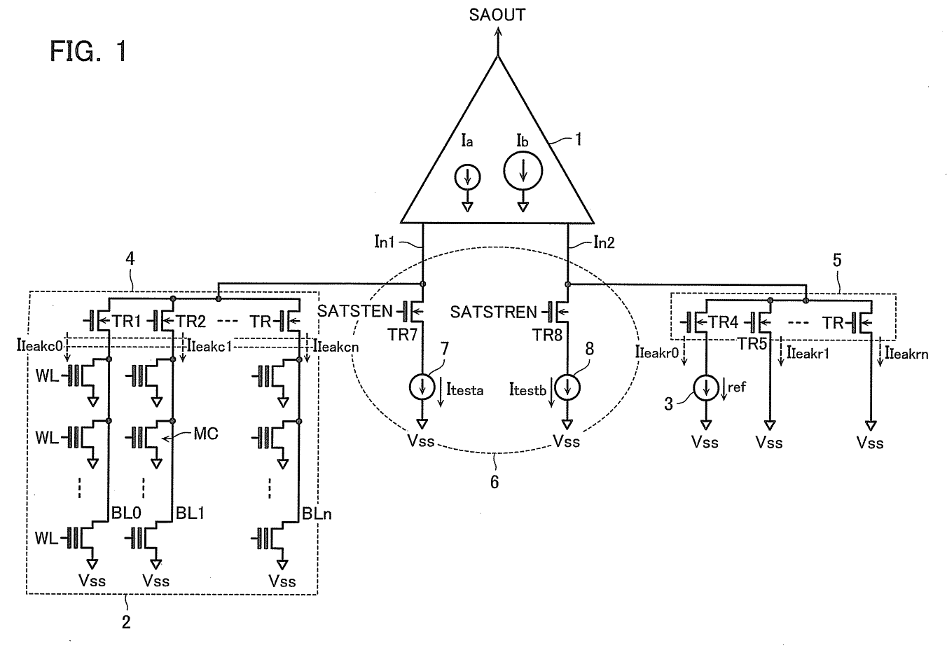

FIG. 1 is a circuit diagram showing a read circuit part in a semiconductor memory device according to a first embodiment of the present invention.

This semiconductor memory device comprises a sense amplifier circuit 1 having a first and a second input terminal In1, In2. The first input terminal In1 of the sense amplifier circuit 1 is connected to a cell array 2 via a first gate circuit or a column selector 4. On the other hand, the second input terminal In2 is connected to a reference current source 3 via a second gate circuit or a replica column selector 5. The first and second input terminals In1, In2 are connected to a test circuit 6.

The sense amplifier circuit 1 is configured to sense/amplify the difference between currents flowing in the first and second input terminals In1, In2 and provide the result to external. The output SAOUT from the sense amplifier circuit 1 is utilized in reading data from a memory cell MC contained in the cell array 2 as described later. The currents flowing in the first and second input terminals In1, In2 contain a first and a second bias current Ia, Ib, respectively.

The cell array 2 is of the NOR-type in the present embodiment and includes a plurality of mutually intersecting word lines WL and bit lines BL and a plurality of memory cells MC arranged at the intersections of the word lines WL and the bit lines BL. The memory cell MC is a flash memory including a floating gate-structured MOS transistor having a source connected to the ground line Vss, a drain connected to the bit line BL, and a gate connected to the word line WL.

The reference current source 3 is provided between the replica column selector 5 and the ground line Vss to feed a reference current Iref to the second input terminal In2 of the sense amplifier circuit 1. The reference current serves as the reference for level sensing the cell current in a selected memory cell MC.

The column selector 4 includes NMOS transistors TR1, TR2 and so forth corresponding to the bit lines BL in the cell array 2. The NMOS transistors have sources connected to the bit lines BL, respectively. On the other hand, the NMOS transistors have drains connected to the first input terminal In1 of the sense amplifier circuit 1 in common. The column selector 4 is used to connect a selected one of the bit lines BL in the cell array 1 to the first input terminal In1 of the sense amplifier circuit 1 and to disconnect all the bit lines BL from the first input terminal In1 of the sense amplifier circuit 1. It should be noted that off-leakage currents Ileakc0, Ileakc1 and so forth may flow as shown with the dotted-line arrows in FIG. 1 even if the transistors TR1, TR2 and so forth are kept off.

The replica column selector 5 is a circuit similar in structure to the column selector 4 and includes plural NMOS transistors TR4, TR5 and so forth. Therefore, with respect to the replica column selector 5, off-leakage currents Ileakr0, Ileakr1 and so forth flow, as shown with the dotted-line arrows in FIG. 1, to the extent almost same as that in the column selector 4.

In an ideal read circuit, the sense amplifier circuit 1 has an offset current Ioffset (=|Ia−Ib|)=0 μA, and the sum total ΣIleakcn of off-leakage currents Ileakcn flowing in non-selected transistors in the column selector 4 and the sum total ΣIleakrn of off-leakage currents Ileakrn flowing in non-selected transistors in the replica column selector 5 have a difference current ΔΣIleakn=0 μA. An In1-side bias current is herein denoted with Ia and an In2-side bias current with Ib. In this case, the sense amplifier circuit 1 simply compares the cell current Icell flowing in the selected memory cell MC with the reference current Iref flowing in the reference current source 3 so that the output SAOUT becomes “H” if the memory cell MC is a first-state cell or an on-cell, that is, Icell>Iref, and “L” in contrast if the memory cell MC is a second-state cell or an off-cell, that is, Icell<Iref.

In practice, however, the offset current Ioffset in the sense amplifier circuit 1 and the difference current ΔΣIleakn between the sum totals (ΣIleakcn and ΣIleakrn) of off-leakage currents flowing in non-selected transistors in the column selector 4 and the replica column selector 5 can not be made 0 μA easily. Therefore, in consideration of the associated influences, the currents flowing in the first and second input terminals In1, In2 of the sense amplifier circuit 1 are represented by Icell+ΣIleakcn+Ia, and Iref+ΣIleakrn+Ib, respectively. In this case, a later-described malfunction may arise as a problem.

In a word, if the selected memory cell MC is an on-cell, Icell>Iref. In this case, the output SAOUT from the sense amplifier circuit 1 becomes “H” originally. If, though, the sum I0 (=Ioffset+ΔΣIleakn) of the offset current and the difference current between the sum totals of off-leakage satisfies Icell<Iref+I0, the current flowing in the input terminal In2 becomes larger than the current flowing In1. As a result, the output SAOUT from the sense amplifier circuit 1 becomes “L” instead. On the other hand, if the selected memory cell MC is an off-cell, Icell<Iref. In this case, the output SAOUT from the sense amplifier circuit 1 becomes “L” originally. If, though, the sum I1 (=Ioffset′+ΔΣIleakn′) of the offset current and the difference current between the sum totals of off-leakage satisfies Icell+Il>Iref, the current flowing in the input terminal In1 becomes larger than the current flowing In2. As a result, the output SAOUT from the sense amplifier circuit 1 becomes “H” instead.

In a supplemental description, if the off-leakage currents Ileakc0, Ileakc1 and so forth in the column selector 4 are so smaller than Icell and Iref that they are negligible, the replica column selector 5 is not needed. In this case, the above-described problem is considered as Icell<Iref+(Ib−Ia) in the case of the on-cell and Icell+(Ia−Ib)>Iref in the case of the off-cell.

A product in the condition that causes the above-described problem (malfunction) should be surely subjected to screening at a test before shipping, which requires a test circuit for that purpose.

The test circuit 6 includes a read circuit test current source 7 connected via a first switching element or an NMOS transistor TR7 controllable with a sense amplifier test enable signal SATSTEN given from external and configured to feed a certain current Itesta. It also includes a read circuit test current source 8 connected via a second switching element or an NMOS transistor TR8 controllable with a sense amplifier test reference enable signal SATSTREN given from external and configured to feed a certain current Itestb. The test circuit 6 is configured to feed the certain currents Itesta, Itestb as superimposed on the currents flowing in the first and second input terminals In1, In2 of the sense amplifier circuit 1. It is used in testing the sense amplifier circuit 1 as described later.

### [Method of Testing Sense Amplifier Circuit 1]

The following description is given to a method of evaluating an operation margin in a read circuit in the present semiconductor memory device.

The offset current Ioffset in the sense amplifier circuit 1 includes an offset current ΔIba (=Ib−Ia) if the In2-side bias current Ib is larger than the In1-side bias current Ia. In this case, an achievement of reliable reading when the selected memory cell MC is an on-cell requires the establishment of a relation of Icell>Iref+ΔIba+(ΣIleakrn−ΣIleakcn) as the worst condition. On the other hand, the offset current Ioffset in the sense amplifier circuit 1 includes an offset current ΔIab (=Ia−Ib) if the In1-side bias current Ia is larger than the In2-side bias current Ib. In this case, an achievement of reliable reading when the selected memory cell MC is an off-cell requires the establishment of a relation of Icell+ΔIab+(ΣIleakcn−ΣIleakrn)<Iref as the worst condition. Therefore, reliable normal operation of semiconductor memory devices for shipping requires screening semiconductor memory devices under the conditions that satisfy the following expressions (1) and (2) when the selected memory cell MC is an on-cell and an off-cell, respectively.

[Expression 1]

Icell≦Iref+ΔIba+(ΣIleakrn−ΣIleakcn) (1)

[Expression 2]

Icell+ΔIab+(ΣIleakcn−ΣIleakrn)≧Iref (2)

Therefore, the following description is given to a method of screening only individuals that satisfy the above expressions (1), (2).

Initially, evaluations are conducted to decide the test currents Itesta and Itestb that satisfy Itesta≦Max[ΔIba+(ΣIleakrn−ΣIleakcn)] and Itestb≦Max[ΔIab+(ΣIleakcn−ΣIleakrn)] where Max[] represents the maximum tolerable current at which the sense amplifier circuit 1 is normally operable.

Subsequently, all the NMOS transistors TR in the column selector 4 and the replica column selector 5 are turned off, followed by setting the sense amplifier test enable signal SATSTEN=“H” and the sense amplifier test reference enable signal SATSTREN=“L” to make the test current Itesta flow in the first input terminal In1. If there is a test individual that satisfies Itesta>ΔIba+(ΣIleakrn−ΣIleakcn), the output SAOUT from the sense amplifier circuit 1 becomes “H”. If there is a test individual that satisfies Itesta≦ΔIba+(ΣIleakrn−ΣIleakcn), the output SAOUT from the sense amplifier circuit 1 becomes “L”. Accordingly, if the output SAOUT from the sense amplifier circuit 1 is “L”, the individual can satisfy the expression (1).

Subsequently, all the NMOS transistors TR in the column selector 4 and the replica column selector 5 are turned off, followed by setting the sense amplifier test enable signal SATSTEN=“L” and the sense amplifier test reference enable signal SATSTREN=“H” to make the test current Itestb flow in the second input terminal In2. If there is a test individual that satisfies Itestb>ΔIab+(ΣIleakcn ΣIleakrn), the output SAOUT from the sense amplifier circuit 1 becomes “L”. If there is a test individual that satisfies Itestb≦ΔIab+(ΣIleakcn−ΣIleakrn), the output SAOUT from the sense amplifier circuit 1 becomes “H”. Accordingly, if the output SAOUT from the sense amplifier circuit 1 is “H”, the individual can satisfy the expression (2).

Through the above steps, it is made possible to screen the individuals that satisfy the above expressions (1), (2). In accordance with this method, the data read part actually used is available as it is and thus the determination result has higher reliability. In addition, the test currents Itesta and Itestb are adjustable and accordingly the determination criterion can be set freely. Further, a determination result can be obtained by only viewing the state of the output SAOUT from the sense amplifier circuit 1. Accordingly, a determination can be made rapidly without measuring the offset currents ΔIab, ΔIba in the sense amplifier circuit 1 and the off-leakage currents Ileakcn and Ileakrn through the column selector 4 and the replica column selector 5.

### [Configuration of Test System]

A system for executing the above test is described next.

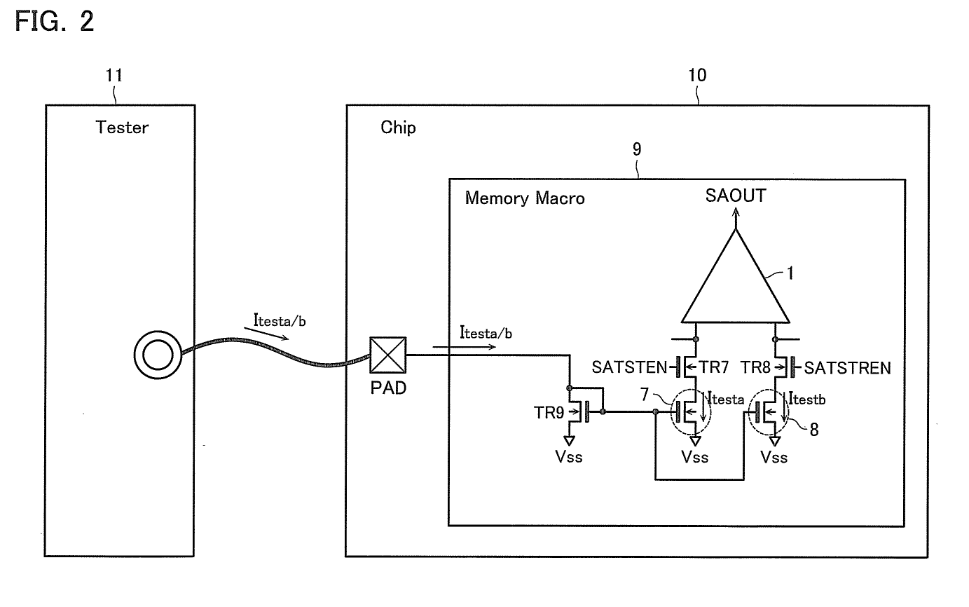

FIG. 2 is a brief diagram of a system including the above semiconductor memory device.

This system comprises a chip 10 having a PAD, and a tester 11 configured to feed the test currents Itesta and Itestb to the PAD on the chip 10.

The chip 10 includes the semiconductor memory device shown in FIG. 1 as well as a memory macro 9 containing an NMOS transistor TR9. The NMOS transistor TR9 has a source connected to the ground line Vss, a drain to the PAD, and a gate to the gates of NMOS transistors contained in the read circuit test current sources 7 and 8. The gate of the NMOS transistor TR9 is connected to the drain thereof. In a word, the read circuit test current sources 7 and 8 and the NMOS transistor TR9 configure current mirror circuits. Therefore, when a desired standard current is fed from the tester 11 via the PAD in the NMOS transistor TR9, desired test currents Itesta and Itestb are allowed to flow in the read circuit test current sources 7 and 8. In a word, it is possible to adjust the test currents Itesta and Itestb directly from external.

### [Configuration of Another Test System]

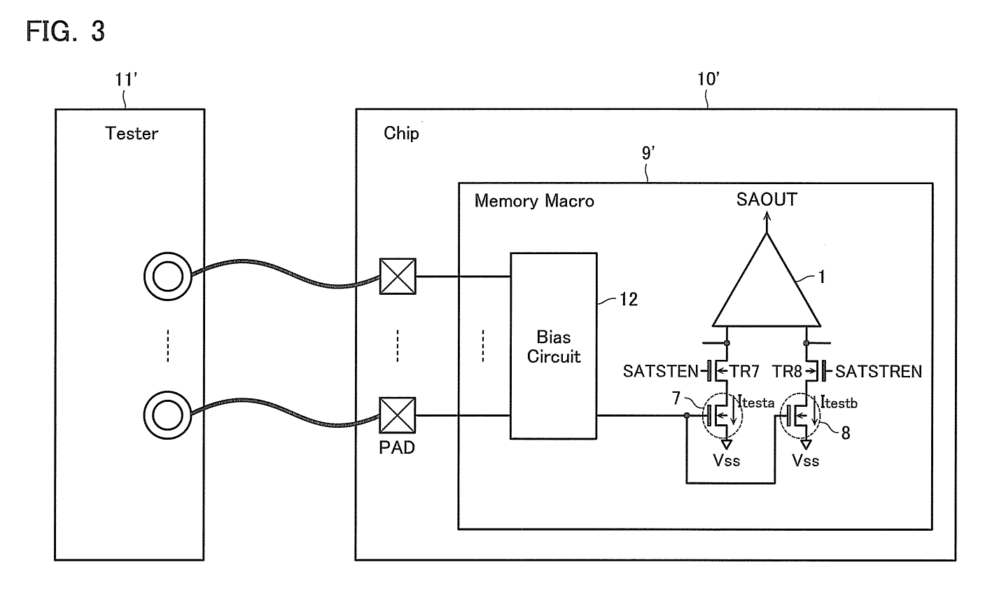

FIG. 3 is a brief diagram of another system including the above semiconductor memory device.

This system comprises a chip 10′ having PADs, and a tester 11′ configured to feed a digital signal to the PADs on the chip 10′.

The chip 10′ includes the semiconductor memory device shown in FIG. 1 as well as a memory macro 9′ containing a bias circuit 12. The bias circuit 12 is configured to apply a bias voltage to the gates of NMOS transistors contained in the read circuit test current sources 7 and 8. The bias circuit is controlled with the digital signal given from the tester 11′ via the PADs. This configuration makes it possible to obtain desired test currents Itesta and Itestb in accordance with the digital signal from the tester 11′. Therefore, this system is suitable for operation from a computer and so forth.

### Second Embodiment

The first embodiment shows the circuitry in consideration of only the off-leakage currents Ileakc, Ileakr in the column selector 4 and the replica column selector 5 and the method of deciding an operation margin in the read circuit using the circuitry.

Besides the off-leakage current Ileakc flowing in non-selected bit lines BL, a bit line-leakage current Ibl-leakc may flow even in the selected bit line BL through non-selected memory cells MC connected to the selected bit line BL. Therefore, a semiconductor memory device designed in consideration of the bit line-leakage current Ibl-leakc and a method of testing the same are shown below.

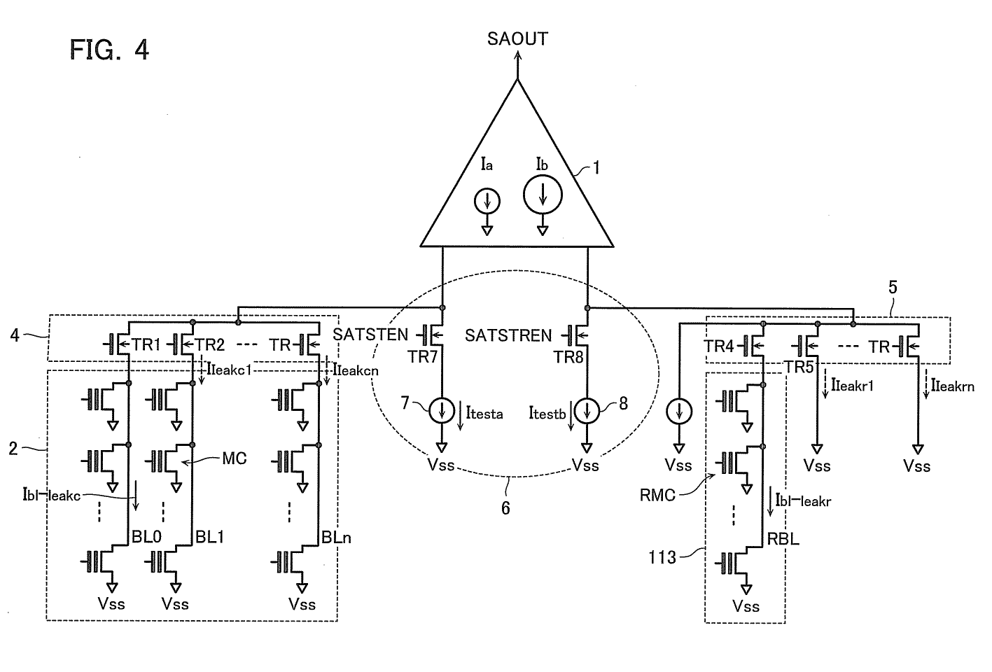

FIG. 4 is a circuit diagram showing a read circuit part in a semiconductor memory device according to a second embodiment of the present invention, in which the same elements as those in FIG. 1 are denoted hereinafter with the same reference numerals and symbols.

This semiconductor memory device is similar to that in FIG. 1 except that the reference current source 3 is connected to the second input terminal of the sense amplifier circuit 1 not via the replica column selector 5, and that there is a replica cell array 113 connected to the second input terminal of the sense amplifier circuit 1 via the replica column selector 5.

The replica cell array 113 has a replica bit line RBL connected to the source of the NMOS transistor TR4 in the replica column selector 5. The replica bit line RBL is provided with plural replica memory cells RMC, which are same as the memory cells RMC.

The following description is given to screening with the use of the semiconductor memory device.

The present embodiment is similar in screening to the first embodiment except the method of deciding the test currents Itesta, Itestb described later.

The decision of the test currents Itesta, Itestb is evaluated in the state in which the reference current source 3 is turned off, the NMOS transistor TR1 in the column selector 4 connected to a certain bit line BL0 is turned on, the NMOS transistor TR4 in the replica column selector 5 connected to the replica bit line RBL is turned on, and NMOS transistors other than the NMOS transistors TR1, TR4 are turned off. The test currents Itesta and Itestb at the time are determined to satisfy Itesta≦Max[ΔIba+(Ibl-leakr−Ibl-leakc)+(ΣIleakrn−ΣIleakcn)] and Itestb≦Max [ΔIab+(Ibl-leakc−Ibl-leakr)+(ΣIleakcn−ΣIleakrn)].

Subsequently, any one of the NMOS transistors TR in the column selector 4 is turned on, all the NMOS transistors TR except TR4 in the replica column selector 5 are turned off, and the word lines WL associated with all the memory cells MC containing the memory cells on the replica bit line are not selected. Then, setting is made as the sense amplifier test enable signal SATSTEN=“H” and the sense amplifier test reference enable signal SATSTREN =“L” to make the test current Itesta flow in the first input terminal In1. In this case, if the output SAOUT from the sense amplifier circuit 1 is made “L”, the associated individual is determined as a failed one.

Subsequently, any one of the NMOS transistors TR in the column selector 4 is turned on, all the NMOS transistors TR except TR4 in the replica column selector 5 are turned off, and the word lines WL associated with all the memory cells MC containing the memory cells on the replica bit line are not selected. Then, setting is made as the sense amplifier test enable signal SATSTEN=“L” and the sense amplifier test reference enable signal SATSTREN=“H” to make the test current Itestb flow in the second input terminal In2. In this case, if the output SAOUT from the sense amplifier circuit 1 is made “H”, the associated individual is determined as a failed one.

The above steps make it possible to achieve screening in consideration of the offset current ΔIab (ΔIba) in the sense amplifier circuit 1 and the off-leakage current Ileakc through the column selector 4 as well as the bit line leakage current Ibl-leakc.

### Third Embodiment

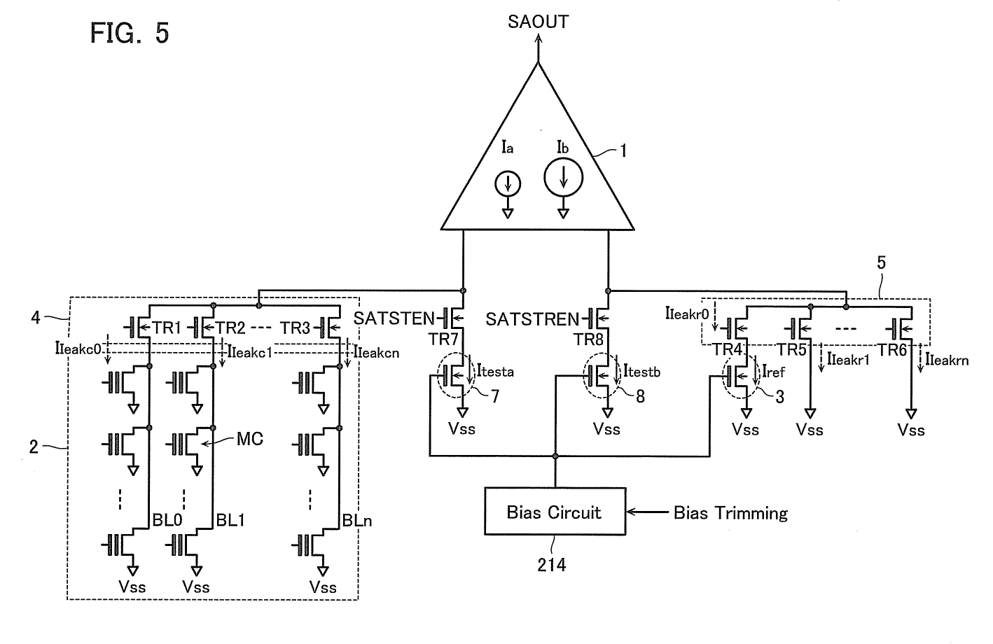

FIG. 5 is a circuit diagram showing a read circuit part in a semiconductor memory device according to a third embodiment of the present invention.

This semiconductor memory device comprises the semiconductor memory device shown in FIG. 1 and an additional bias circuit 214 for trimming the reference current source 3 with a bias trimming signal given from external. The output from the bias circuit 214 is supplied not only to the reference current source 3 but also to the read circuit test current sources 7 and 8 in common. Therefore, it is capable of trimming the read circuit test current sources 7 and 8 in engagement with the reference current source 3.

In accordance with the present embodiment, the common bias circuit 214 can control the reference current Iref and the test currents Itesta, Itestb such that the trimming result on the reference current Iref can be fed back to trimming the test currents Itesta, Itestb. In a word, not only the reference current source 3 but also the read circuit test current sources 7 and 8 can be always subjected to optimal current trimming.

### Fourth Embodiment

The first through third embodiments describe the semiconductor memory device suitable for evaluating individuals with possible occurrences of failed read due to the influence by disturbance currents other than the cell current Icell and the reference current Iref and the screening method with the use of the same.

The read circuit test current sources 7 and 8 may also be operated during actual read in the semiconductor memory device to exert the effect on preventing failed read.

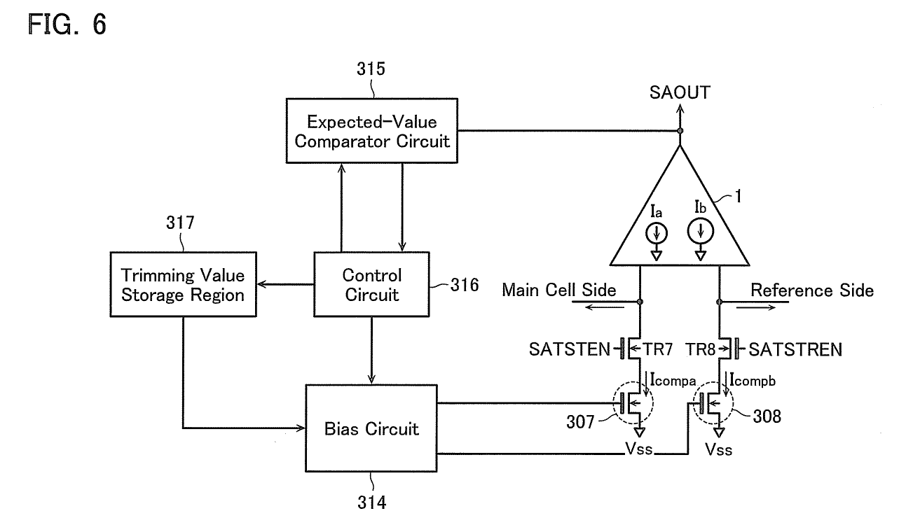

FIG. 6 is a block diagram of a semiconductor memory device according to a fourth embodiment of the present invention.

This semiconductor memory device comprises disturbance current cancelling current sources 307 and 308 in place of the read circuit test current sources 7 and 8. It also comprises a bias circuit 314 configured to control these disturbance current cancelling current sources 307 and 308; a trimming value storage region 317 for storing trimming values given to the bias circuit 314; an expected-value comparator 315 configured to compare the output SAOUT from the sense amplifier circuit 1 with an expected value; and a control circuit 316 configured to control the trimming value storage region 317 and the expected-value comparator 315. These disturbance current cancelling current sources 307 and 308 are same as the read circuit test current sources 7 and 8.

The following description is given to a method of adjusting disturbance current cancelling currents Icompa, Icompb.

Initially, all the bit lines BL are not selected, or all the memory cells MC connected to the selected bit line BL are not selected. As a result, the first and second input terminals of the sense amplifier circuit 1 are supplied only with disturbance current flows.

Subsequently, the control circuit 316 makes a setting in the expected-value comparator circuit 315 with an expected value of the output from the sense amplifier circuit 1 on normal read from a memory cell MC or an on-cell (hereinafter referred to as a “first expected value”).

Subsequently, reading is executed while the disturbance current cancelling current sources 307, 308 are turned off. Then, the first expected value is compared with the output SAOUT from the sense amplifier circuit 1 and, if no match occurs, the disturbance current cancelling current source 307 is turned on to feed a certain current from the bias circuit 314, followed by reading again. Then, the first expected value is compared with the output SAOUT from the sense amplifier circuit 1 and reading is repeated with increases in the disturbance current cancelling current Icompa until a match occurs therebetween. As a result, if the first expected value matches with the output SAOUT from the sense amplifier circuit 1, the bias setting at that time is stored as a first bias setting in the trimming value storage region 317.

Subsequently, the control circuit 317 makes a setting in the expected-value comparator circuit 315 with an expected value of the output from the sense amplifier circuit 1 on normal read from a memory cell MC or an off-cell (hereinafter referred to as a “second expected value”).

Subsequently, the disturbance current cancelling current source 308 is turned on to feed a certain current from the bias circuit 314, followed by reading. Then, the second expected value is compared with the output SAOUT from the sense amplifier circuit 1 and reading is repeated with increases in the disturbance current cancelling current Icompb until a match occurs therebetween. As a result, if the second expected value matches with the output SAOUT from the sense amplifier circuit 1, the bias setting at that time is stored as a second bias setting in the trimming value storage region 317.

The first and second bias settings thus obtained are used to operate the disturbance current cancelling current sources 307 and 308, thereby suppressing failed read on reading from the semiconductor memory device.

The present embodiment makes it possible to use the test circuit on the influence by disturbance currents as it is to reduce malfunctions at the time of read in the semiconductor memory device.

### Others

The embodiments of the invention have been described above though the present invention is not limited to these but rather can be applied to semiconductor memory devices of the type that compare a cell current with a reference current at a sense amplifier circuit for data read. In the above embodiments the present invention is applied to the NOR-type flash memory though the present invention is also applicable to semiconductor memory devices of other types such as the NAND-type flash memory.

What is claimed is:

1. A semiconductor memory device, comprising:
a sense amplifier circuit having a first and a second input terminal, said sense amplifier configured to compare current flowing in said first input terminal with current flowing in said second input terminal, and said sense amplifier configured to provide the result to external;
a first gate circuit connected to said first input terminal, said first gate circuit configured to pass a cell current flowing in a memory cell to said first input terminal;
a reference current source, said reference current source configured to feed a reference current to said second input terminal, said reference current serving as the reference for level sensing said cell current;
a second gate circuit connected to said second input terminal, said second gate circuit including a replica circuit of said first gate circuit;
a first current source configured to feed a first current to said first input terminal, said first current corresponding to the offset at the time of read from a first-state cell; and
a second current source configured to feed a second current to said second input terminal, said second current corresponding to the offset at the time of read from a second-state cell.

2. The semiconductor memory device according to claim 1, further comprising:
a first switching element configured to electrically connect/disconnect said first input terminal to/from said first current source; and
a second switching element configured to electrically connect/disconnect said second input terminal to/from said second current source.

3. The semiconductor memory device according to claim 1, wherein said reference current flows in said second input terminal via said second gate circuit.

4. The semiconductor memory device according to claim 1, further comprising a pad for supplying a standard current to set said first and second currents,
wherein said first and second current sources are current mirror circuits configured to receive said standard current as the input current and provide said first and second currents as the output currents, respectively.

5. The semiconductor memory device according to claim 1, further comprising:
a pad for receiving a digital signal; and
a bias circuit configured to generate a bias voltage based on said digital signal,
wherein said first and second current sources comprise transistors configured to receive said bias voltage as the gate voltage.

6. The semiconductor memory device according to claim 1, further comprising:
a memory cell array connected to said first gate circuit and including a plurality of mutually intersecting first and second lines, and a plurality of memory cells connected at intersections of said first and second lines; and
a replica cell array including a replica circuit of said memory cell array.

7. The semiconductor memory device according to claim 1, further comprising a bias circuit configured to control said reference current source and said first and second current sources in common.

8. The semiconductor memory device according to claim 7, further comprising a control information storage unit configured to store control information for said bias circuit to adjust the current value of said reference current,
wherein said bias circuit controls said first and second current sources based on said control information in said control information storage unit.

9. The semiconductor memory device according to claim 8, wherein said control information includes
a first setting associated with said first current at the time when the output from said sense amplifier circuit meets the output expected at the time of said first cell-state read, and
a second setting associated with said second current at the time when the output from said sense amplifier circuit meets the output expected at the time of said second cell-state read.

10. A semiconductor memory device, comprising:
a sense amplifier circuit having a first and a second input terminal, said sense amplifier configured to compare current flowing in said first input terminal with current flowing in second input terminal, and said sense amplifier configured to provide the result to external;
a first gate circuit connected to said first input terminal, said first gate circuit configured to pass a cell current flowing in a memory cell to said first input terminal;
a reference current source, said reference current source configured to feed a reference current to said second input terminal, said reference current serving as the reference for level sensing said cell current;
a second gate circuit connected to said second input terminal, said second gate circuit including a replica circuit of said first gate circuit;
a first current source configured to feed a first current to said first input terminal, said first current being equal to or smaller than the maximum tolerable value, at which said sense amplifier circuit is normally operable, of a sum current of a difference obtained by subtracting a first bias current flowing in said first input terminal from a second bias current flowing in said second input terminal and a difference obtained by subtracting an off-leakage current through said first gate circuit from an off-leakage current through said second gate circuit; and
a second current source configured to feed a second current to said second input terminal, said second current being equal to or smaller than the maximum tolerable value, at which said sense amplifier circuit is normally operable, of a sum current of a difference obtained by subtracting said second bias current from said first bias current and a difference obtained by subtracting the off-leakage current through said second gate circuit from the off-leakage current through said first gate circuit.

11. The semiconductor memory device according to claim 10, wherein said reference current flows in said second input terminal via said second gate circuit.

12. The semiconductor memory device according to claim 10, further comprising a pad for supplying a standard current to set said first and second currents,
wherein said first and second current sources are current mirror circuits configured to receive said standard current as the input current and provide said first and second currents as the output currents, respectively.

13. The semiconductor memory device according to claim 10, further comprising:
a pad for receiving a digital signal; and
a bias circuit configured to generate a bias voltage based on said digital signal,
wherein said first and second current sources comprise transistors configured to receive said bias voltage as the gate voltage.

14. The semiconductor memory device according to claim 10, further comprising:
a memory cell array connected to said first gate circuit and including a plurality of mutually intersecting first and second lines, and a plurality of memory cells connected at intersections of said first and second lines; and
a replica cell array including a replica circuit of said memory cell array.

15. The semiconductor memory device according to claim 10, further comprising a bias circuit configured to control said reference current source and said first and second current sources in common.

16. The semiconductor memory device according to claim 15, further comprising a control information storage unit configured to store control information for said bias circuit to adjust the current value of said reference current,
wherein said bias circuit controls said first and second current sources based on said control information in said control information storage unit.

17. The semiconductor memory device according to claim 16, wherein said control information includes
a first setting associated with said first current at the time when the output from said sense amplifier circuit meets the output expected at the time of read from said first-state cell, and
a second setting associated with said second current at the time when the output from said sense amplifier circuit meets the output expected at the time of read from said first-state cell.

18. A method of inspecting semiconductor memory devices, comprising:
feeding a previously set current from said first current source to said semiconductor memory device as recited in claim 1 while keeping said first and second gate circuits turned off to confirm that a first expected value is provided from said sense amplifier circuit; and
feeding a previously set current from said second current source to said semiconductor memory device while keeping said first and second gate circuits turned off to confirm that a second expected value is provided from said sense amplifier circuit.

19. The method of inspecting semiconductor memory devices according to claim 18, wherein said first current is equal to or smaller than the maximum tolerable value, at which said sense amplifier circuit is normally operable, of a sum current of a difference obtained by subtracting a first bias current flowing in said first input terminal from a second bias current flowing in said second input terminal and a difference obtained by subtracting an off-leakage current through said first gate circuit from an off-leakage current through said second gate circuit,
said second current is equal to or smaller than the maximum tolerable value, at which said sense amplifier circuit is normally operable, of a sum current of a difference obtained by subtracting said second bias current from said first bias current and a difference obtained by subtracting the off-leakage current through said second gate circuit from the off-leakage current through said first gate circuit.

20. The method of inspecting semiconductor memory devices according to claim 18, wherein said semiconductor memory device includes
a memory cell array connected to said first gate circuit and including a plurality of lines, and a plurality of memory cells connected to said lines, and
a replica cell array connected to said second gate circuit and including replica lines having a structure equal to that of said lines, and replica memory cells connected to said replica lines and having a structure equal to that of said memory cells,
said first current is equal to or smaller than the maximum tolerable value, at which said sense amplifier circuit is normally operable, of a sum current of a difference obtained by subtracting a first bias current flowing in said first input terminal from a second bias current flowing in said second input terminal, a difference obtained by subtracting leakage currents flowing in said lines from leakage currents flowing in said replica lines and a difference obtained by subtracting an off-leakage current through said first gate circuit from an off-leakage current through said second gate circuit,
said second current is equal to or smaller than the maximum tolerable value, at which said sense amplifier circuit is normally operable, of a sum current of a difference obtained by subtracting said second bias current from said first bias current, a difference obtained by subtracting the leakage currents flowing in said lines from the leakage currents flowing in said replica lines and a difference obtained by subtracting the off-leakage current through said second gate circuit from the off-leakage current through said first gate circuit.
